(19) United States
(12) Patent Application Publication
(10) Pub. No.: US 2014/0129905 A1
(43) Pub. Date: May 8, 2014

(54) Flexible Low Density Parity Check Code Seed

(71) Applicant: LSI CORPORATION, Milpitas, CA (US)

(72) Inventors: Lei Chen, Santa Clara, CA (US); Shaohua Yang, San Jose, CA (US); Johnson Yen, Fremont, CA (US)

(73) Assignee: LSI CORPORATION, Milpitas, CA (US)

(21) Appl. No.: 13/670,393

(22) Filed: Nov. 6, 2012

(51) Int. Cl. H03M 13/13; H03M 13/27

(52) U.S. Cl. 714/770; 714/769; 714/E11.034

(57) ABSTRACT

Various embodiments of the present inventions provide systems and methods for data processing with a flexible LDPC seed.

### BACKGROUND

Various data processing systems have been developed including storage systems, cellular telephone systems, and radio transmission systems. In each of the systems data is transferred from a sender to a receiver via some medium. For example, in a storage system, data is sent from a sender (i.e., a write function) to a receiver (i.e., a read function) via a storage medium. As information is stored and transmitted in the form of digital data, errors are introduced that, if not corrected, can corrupt the data and render the information unusable. The effectiveness of any transfer is impacted by any losses in data caused by various factors. Many types of data processors have been developed to detect and correct errors in digital data. For example, data detectors and decoders such as Maximum a Posteriori (MAP) detectors and Low Density Parity Check (LDPC) decoders may be used to detect and decode the values of data bits or multi-bit symbols retrieved from storage or transmission systems. Such detectors and decoders may be used in a loop to iteratively process data, with each being guided by the output of the other to process the data. An interleaver may be used to prepare data for decoding in the LDPC decoder, which is particularly sensitive to burst errors that concentrate errors in a localized run of data. The interleaver spreads burst errors across the block of data, making it appear more like random data, which the LDPC is better adapted to correct.

### BRIEF SUMMARY

Various embodiments of the present inventions provide systems and methods for data processing with a flexible LDPC seed. In some embodiments, the LDPC seed comprises a known value data segment such as a logical block address (LBA) written to a magnetic hard drive and associated with a data sector to identify the sector. The log likelihood ratio (LLR) values for the LDPC seed may be set to particular values at various times during global detection and decoding iterations to promote data convergence in an LDPC decoder. In some embodiments, programmable registers are provided for one or more of a global iteration number threshold, a high LLR value and a low LLR value. At or near the beginning of the global iterations, the LLR values for the LDPC seed are set to the high LLR value. When the global iteration number reaches the global iteration number threshold, the LLR values for the LDPC seed are set to the low LLR value. In some embodiments, the LLR values for the LDPC seed are set in the output of a data detector prior to decoding in the LDPC decoder, and prior to interleaving processes which would break up the data bits for the LDPC seed. The LLR values are thus set when the LDPC seed data bits for a data sector are still in a contiguous block.

This summary provides only a general outline of some embodiments according to the present inventions. Many other objects, features, advantages and other embodiments of the present inventions will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals may be used throughout several drawings to refer to similar components.

FIG. 1 depicts a data storage system including a data processing system with flexible LDPC seed in accordance with some embodiments of the present inventions;

FIG. 2 depicts a data transmission system including a data processing system with flexible LDPC seed in accordance with some embodiments of the present inventions;

FIG. 3 depicts a diagram of data sectors with LDPC seeds as they may be read from a data storage device or data transmission system in accordance with some embodiments of the present inventions;

FIG. 4 depicts a block diagram of a read channel with a flexible LDPC seed circuit which may be used to retrieve or receive stored or transmitted data in accordance with some embodiments of the present inventions;

FIG. 5 depicts a block diagram of a flexible LDPC seed circuit in accordance with some embodiments of the present inventions; and

FIG. 6 depicts a flow diagram showing a method for data processing with flexible LDPC seed in accordance with some embodiments of the present inventions.

### DETAILED DESCRIPTION OF THE INVENTION

Various embodiments of the present inventions are related to apparatuses and methods for data processing systems with flexible LDPC seed. The data processing system performs functions such as error detection and correction on data sectors, including decoding codewords representing each data sector in an LDPC decoder. The blocks of data have LDPC seeds, which in some embodiments are known data values such as, but not limited to, logical block address (LBA) values that identify each data block. At the first global processing iteration in the data processing system, log likelihood ratio (LLR) values representing the probabilities of potential values for each data bit or symbol in the LDPC seed are set to a programmable “high” LLR value. When the global iteration number reaches a programmable global iteration number threshold, the LLR values for the LDPC seed are set to a programmable “low” LLR value.

Because the LDPC seed is a known value, originally setting the LLR values for the LDPC seed to high values can promote convergence of the data sector in the LDPC decoder. However, if the LDPC seed values have been corrupted by noise, leaving the LLR values for the LDPC seed at high values can actually slow or prevent convergence of the data sector. If the data converges early, decoding may be complete before the global iteration number reaches the programmable global iteration number. If the data has not converged before the global iteration number is reached a programmable global iteration number, resetting the LLR values for the LDPC seed at the lower value enables the LDPC decoder to adjust the LLR values for the LDPC seed and for data bits or symbols that are connected to the LDPC seed in the H matrix for the LDPC code. Thus, the LDPC seed is made flexible, helping the data to converge in the LDPC decoder whether the LDPC seed has the correct known values or has been corrupted by noise.

In some embodiments, the global iteration number threshold, the high LLR value and the low LLR value are programmable, providing additional flexibility in setting the LLR values for the LDPC seed. In some embodiments, the high LLR value is the maximum LLR value, indicating the highest possible likelihood that the perceived value of the LDPC seed is correct. Decoding thus begins with the assumption that the LDPC seed is correct. In some embodiments, the low LLR value is a neutral value that indicates no preference for any possible value for the LDPC seed. For example, with a binary LDPC decoder, each bit in the LDPC seed may be 0 or 1, and the LLR values for the LDPC seed bits are set to 0, indicating that the LDPC seed bits are equally likely to be 0 as to be 1. (The LLR value for a binary bit is the log of the probability that the bit is 0 divided by the probability that the bit is 1, and an LLR value of 0 denotes an equal probability of each.) For non-binary or multi-level LDPC decoders, the LLR value representing neutral or equal likelihoods may be a value other than 0.

Data processing systems with flexible LDPC seeds as disclosed herein are applicable to processing data stored in or transmitted over virtually any channel or storage of information on virtually any media. Transmission applications include, but are not limited to, optical fiber, radio frequency channels, wired or wireless local area networks, digital subscriber line technologies, wireless cellular, Ethernet over any medium such as copper or optical fiber, cable channels such as cable television, and Earth-satellite communications. Storage applications include, but are not limited to, hard disk drives, compact disks, digital video disks, magnetic tapes and memory devices such as DRAM, NAND flash, NOR flash, other non-volatile memories and solid state drives. For example, the data processing system may be, but is not limited to, a read channel in a magnetic hard disk drive, detecting and decoding data sectors from the drive.

The term “sector” is used herein with respect to several embodiments, but may be considered to refer generally to a block of data with an LDPC seed, that is processed in a data processing system with flexible LDPC seed, regardless of the source or format of the data. Again, the LDPC seed is a known data value in the data sector, for example but not limited to an LBA that identifies the data sector. The term “flexible LDPC seed” indicates that the setting of LLR values for the LDPC seed before it is decoded in an LDPC decoder are set to different values at different global processing iterations, and in some embodiments that the actual LLR values are programmable.

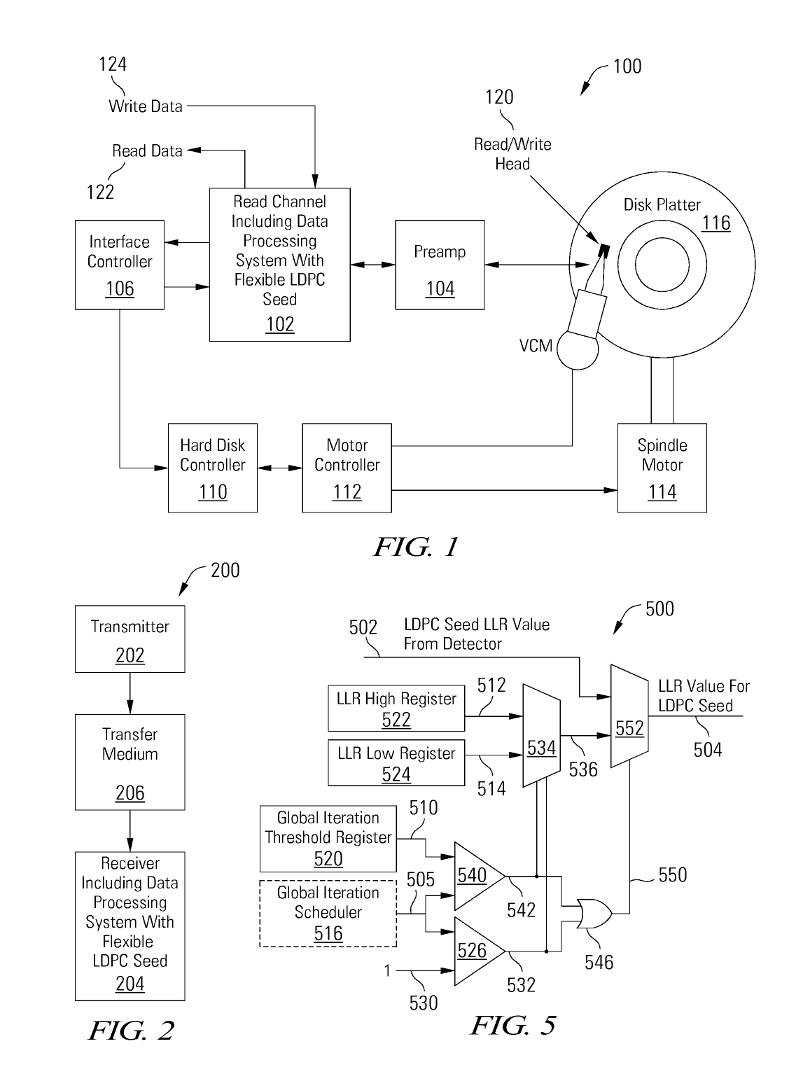

Although the data processing system with flexible LDPC seed disclosed herein is not limited to any particular application, several applications are presented in FIGS. 1 and 2 that benefit from embodiments of the present inventions. Turning to FIG. 1, a storage system 100 is illustrated including a data processing system with flexible LDPC seed in accordance with some embodiments of the present inventions. The storage system 100 includes a read channel circuit 102 with a data processing system with flexible LDPC seed in accordance with some embodiments of the present inventions. Storage system 100 may be, for example, a hard disk drive. Storage system 100 also includes a preamplifier 104, an interface controller 106, a hard disk controller 110, a motor controller 112, a spindle motor 114, a disk platter 116, and a read/write head assembly 120. Interface controller 106 controls addressing and timing of data to/from disk platter 116. The data on disk platter 116 consists of groups of magnetic signals that may be detected by read/write head assembly 120 when the assembly is properly positioned over disk platter 116. In one embodiment, disk platter 116 includes magnetic signals recorded in accordance with either a longitudinal or a perpendicular recording scheme.

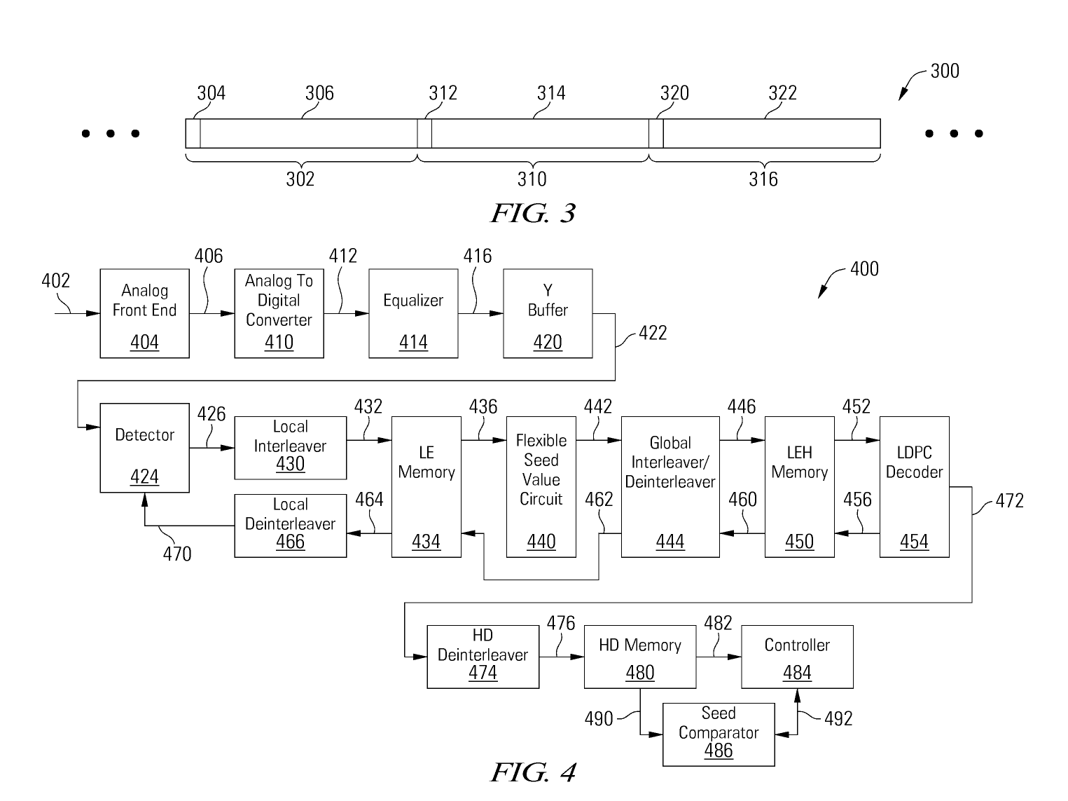

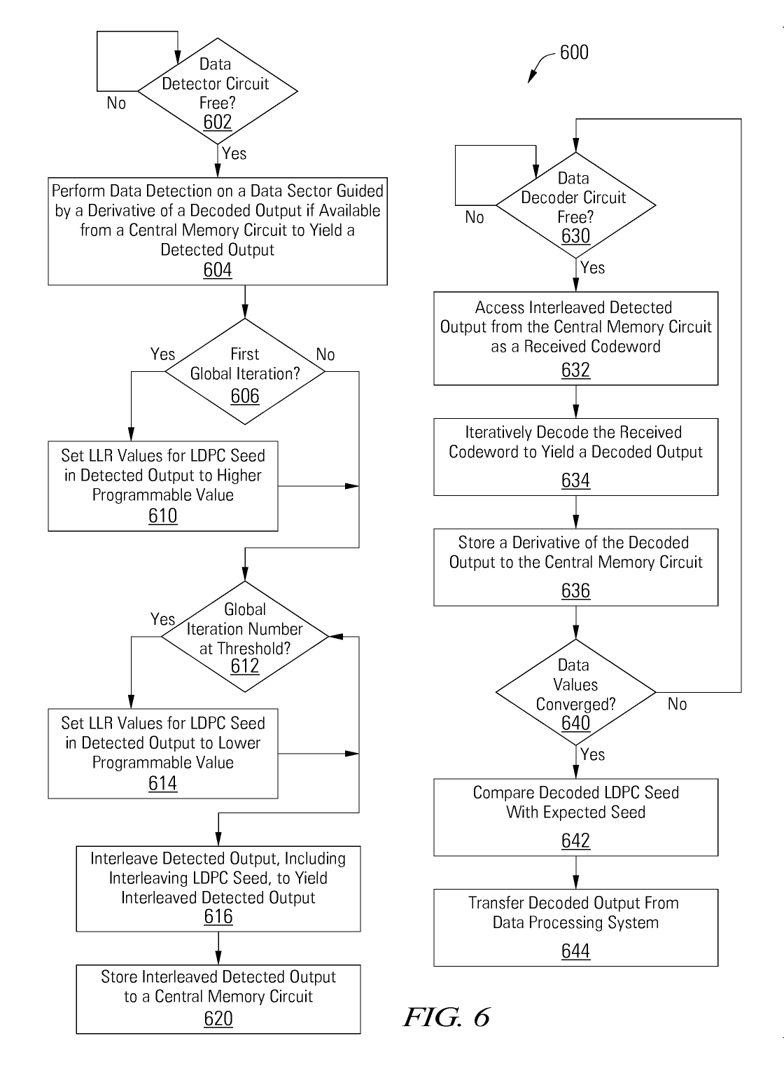

In a typical read operation, read/write head assembly 120 is accurately positioned by motor controller 112 over a desired data track on disk platter 116. Motor controller 112 both positions read/write head assembly 120 in relation to disk platter 116 and drives spindle motor 114 by moving read/write head assembly 120 to the proper data track on disk platter 116 under the direction of hard disk controller 110. Spindle motor 114 spins disk platter 116 at a determined spin rate (RPMs). Once read/write head assembly 120 is positioned adjacent the proper data track, magnetic signals representing data on disk platter 116 are sensed by read/write head assembly 120 as disk platter 116 is rotated by spindle motor 114. The sensed magnetic signals are provided as a continuous, minute analog signal representative of the magnetic data on disk platter 116. This minute analog signal is transferred from read/write head assembly 120 to read channel circuit 102 via preamplifier 104. Preamplifier 104 is operable to amplify the minute analog signals accessed from disk platter 116. In turn, read channel circuit 102 decodes and digitizes the received analog signal to recreate the information originally written to disk platter 116. This data is provided as read data 122 to a receiving circuit. As part of decoding the received information, read channel circuit 102 processes the received signal using a data processing system with flexible LDPC seed. Such a data processing system with flexible LDPC seed may be implemented consistent with that disclosed below in relation to FIGS. 3-5. In some cases, the data processing may be performed consistent with the flow diagram disclosed below in relation to FIG. 6. A write operation is substantially the opposite of the preceding read operation with write data 124 being provided to read channel circuit 102. This data is then encoded and written to disk platter 116.

It should be noted that storage system 100 may be integrated into a larger storage system such as, for example, a RAID (redundant array of inexpensive disks or redundant array of independent disks) based storage system. Such a RAID storage system increases stability and reliability through redundancy, combining multiple disks as a logical unit. Data may be spread across a number of disks included in the RAID storage system according to a variety of algorithms and accessed by an operating system as if it were a single disk. For example, data may be mirrored to multiple disks in the RAID storage system, or may be sliced and distributed across multiple disks in a number of techniques. If a small number of disks in the RAID storage system fail or become unavailable, error correction techniques may be used to recreate the missing data based on the remaining portions of the data from the other disks in the RAID storage system. The disks in the RAID storage system may be, but are not limited to, individual storage systems such storage system 100, and may be located in close proximity to each other or distributed more widely for increased security. In a write operation, write data is provided to a controller, which stores the write data across the disks, for example by mirroring or by striping the write data. In a read operation, the controller retrieves the data from the disks. The controller then yields the resulting read data as if the RAID storage system were a single disk.

Turning to FIG. 2, a wireless communication system 200 or data transmission device including a receiver 204 with a data processing system with flexible LDPC seed is shown in accordance with some embodiments of the present inventions. Communication system 200 includes a transmitter 202 that is operable to transmit encoded information via a transfer medium 206 as is known in the art. The encoded data is received from transfer medium 206 by receiver 204. Receiver 204 incorporates a data processing system with flexible LDPC seed. Such a data processing system with flexible LDPC seed may be implemented consistent with that described below in relation to FIGS. 3-5. In some cases, the data processing may be done consistent with the flow diagram discussed below in relation to FIG. 6.

Turning to FIG. 3, a data stream 300 to be processed in a data processing system with flexible LDPC seed is illustrated in accordance with some embodiments of the present inventions. Each data sector 404, 410, 316 includes an LDPC seed 402, 312, 424 and a corresponding codeword 406, 314, 426. The codewords 406, 314, 426 correspond in some embodiments to LDPC encoded user data bits or symbols, and the LDPC seeds 402, 312, 424 correspond in some embodiments to known data such as, but not limited to, LBA values that identify the data sectors. The LDPC seeds 402, 312, 424 may be in any location relative to their corresponding codewords, such as before, after, or embedded within the codewords.

Turning to FIG. 4, a data processing system 400 with flexible LDPC seed is depicted in accordance with one or more embodiments of the present inventions. Data processing system 400 includes an analog front end circuit 404 that receives an analog signal 402. Analog front end circuit 404 processes analog signal 402 and provides a processed analog signal 406 to an analog to digital converter circuit 410. Analog front end circuit 404 may include, but is not limited to, an analog filter and an amplifier circuit as are known in the art. Based upon the disclosure provided herein, one of ordinary skill in the art will recognize a variety of circuitry that may be included as part of analog front end circuit 404. In some cases, analog signal 402 is derived from a read/write head assembly (e.g., 120) that is disposed in relation to a storage medium (e.g., 116). In other cases, analog signal 402 is derived from a receiver circuit (e.g., 204) that is operable to receive a signal from a transmission medium (e.g., 206). The transmission medium may be wired or wireless. Based upon the disclosure provided herein, one of ordinary skill in the art will recognize a variety of sources from which analog input 402 may be derived.

Analog to digital converter circuit 410 converts processed analog signal 406 into a corresponding series of digital samples 412. Analog to digital converter circuit 410 may be any circuit known in the art that is capable of producing digital samples corresponding to an analog input signal. Based upon the disclosure provided herein, one of ordinary skill in the art will recognize a variety of analog to digital converter circuits that may be used in relation to different embodiments of the present inventions. Digital samples 412 are provided to an equalizer circuit 414. Equalizer circuit 414 applies an equalization algorithm to digital samples 412 to yield an equalized output 416. In some embodiments of the present inventions, equalizer circuit 414 is a digital finite impulse response filter circuit as are known in the art. Equalized output 416 is stored in a Y buffer 420 until a data detector circuit 424 is available to process stored codeword 422. In other cases, equalizer 414 includes sufficient memory to maintain one or more codewords until a data detector circuit 424 is available for processing. It may be possible that equalized output 416 may be received directly from a storage device in, for example, a solid state storage system. In such cases, analog front end circuit 404, analog to digital converter circuit 410 and equalizer circuit 414 may be eliminated where the data is received as a digital data input.

Data detector circuit 424 is operable to apply a data detection algorithm to a received codeword or data set, and in some cases data detector circuit 424 can process two or more codewords in parallel. In some embodiments of the present inventions, data detector circuit 424 is a Viterbi algorithm data detector circuit as is known in the art. In other embodiments of the present inventions, data detector circuit 424 is a maximum a posteriori data detector circuit as is known in the art. Of note, the general phrases “Viterbi data detection algorithm” or “Viterbi algorithm data detector circuit” are used in their broadest sense to mean any Viterbi detection algorithm or Viterbi algorithm detector circuit or variations thereof including, but not limited to, bi-direction Viterbi detection algorithm or bi-direction Viterbi algorithm detector circuit. Also, the general phrases “maximum a posteriori data detection algorithm” or “maximum a posteriori data detector circuit” are used in their broadest sense to mean any maximum a posteriori detection algorithm or detector circuit or variations thereof including, but not limited to, simplified maximum a posteriori data detection algorithm and a max-log maximum a posteriori data detection algorithm, or corresponding detector circuits. Based upon the disclosure provided herein, one of ordinary skill in the art will recognize a variety of data detector circuits that may be used in relation to different embodiments of the present inventions. Data detector circuit 424 is started based upon availability of a data set from equalizer circuit 414 or from a central memory circuit 434.

Upon completion, data detector circuit 424 provides detector output 426. Detector output 426 includes soft data. As used herein, the phrase “soft data” is used in its broadest sense to mean reliability data with each instance of the reliability data indicating a likelihood that a corresponding bit position or group of bit positions has been correctly detected. In some embodiments of the present inventions, the soft data or reliability data is log likelihood ratio (LLR) data as is known in the art. Detected output 426 is provided to a local interleaver circuit 430. Local interleaver circuit 430 is operable to shuffle sub-portions (i.e., local chunks) of the data set included as detected output 426 and provides an interleaved codeword 432 that is stored to central memory circuit 330. Interleaver circuit 430 may be any circuit known in the art that is capable of shuffling data sets to yield a re-arranged data set. In this embodiment, the LDPC seed in the interleaved codeword 432 remains in a contiguous block as in the detected output 426 and is not shuffled or broken up by local interleaver circuit 430. Interleaved codeword 432 is stored in LE memory 434.

The interleaved codeword 432 is accessed from LE memory 434 as a stored codeword 436 by a flexible seed value circuit 440 that sets the LLR values for the LDPC seed during various global iterations in the data processing system 400. (The flexible seed value circuit 440 is also referred to herein as an LLR value setting circuit.) LLR values represent the probability or likelihood that a bit (or a multi-bit data symbol) have a particular value. For example, in a binary system using data bits, a data bit may have a value of 0 or 1, and an LLR value may be provided as the log likelihood ratio of the probability that the bit is 0, divided by the probability that the bit is 1. In other systems, multi-bit data symbols may be used, such as a 2-bit system in which a data symbol may have the values 00, 01, 10 or 11. In such a system, an LLR value may be provided for each possible value for a data symbol. In non-binary or multi-level systems, the possible values for a data symbol are elements of a Galois Field. The detected output 426 is not limited to any particular data format, and one of ordinary skill in the art will recognize a number of data formats that may be used in relation to different embodiments of the present inventions.

The flexible seed value circuit 440 is operable to set LLR values for the LDPC seed in the stored codeword 436, yielding an adjusted-seed output 442. The flexible seed value circuit 440 in some embodiments sets the LLR values for the LDPC seed in the stored codeword 436 to a user-programmable high LLR value, such as the maximum possible LLR value, during the first global iteration of the codeword through the data processing system 400. The flexible seed value circuit 440 in some embodiments sets the LLR values for the LDPC seed in the stored codeword 436 to a user-programmable low LLR value, such as 0 or another neutral value representing balanced probabilities for the possible values, when the global iteration number reaches a user-programmable global iteration number threshold. The LLR values are thus set when the LDPC seed data bits for a data sector are still in a contiguous block, such as in the output of the data detector 424 but before an interleaving process which would break up the data bits for the LDPC seed.

The adjusted-seed output 442 is globally interleaved by a global interleaver/deinterleaver circuit 444, yielding an interleaved output 446 that is stored in a central memory circuit or LEH memory 450. Global interleaver/deinterleaver circuit 444 may be any circuit known in the art that is capable of globally rearranging codewords. In some embodiments, the LDPC seed is broken up by the global interleaver/deinterleaver circuit 444 to spread out any burst errors in the LDPC seed so that the LDPC decoder can better correct the burst errors. The local interleaver circuit 430 and global interleaver/deinterleaver circuit 444 may comprise any suitable circuits for rearranging data, such as but not limited to those disclosed in U.S. patent application Ser. No. 13/305,551 filed Nov. 28, 2011 for a “Variable Sector Size Interleaver”, which is incorporated herein for all purposes. In some embodiments, the local interleaver circuit 430 is operable to rearrange data segments within a portion of a codeword, and the global interleaver/deinterleaver circuit 444 is operable to rearrange data segments across the entire codeword. However, some embodiments of a data processing system with flexible seed value circuit perform other interleaving functions or do not include an interleaving circuit.

A decoder input codeword 452 is retrieved from the LEH memory 450 and is decoded in a low density parity check (LDPC) decoder 454. Based upon the disclosure provided herein, one of ordinary skill in the art will recognize other decode algorithms that may be used in relation to different embodiments of the present inventions. The LDPC decoder 454 applies a data decode algorithm to decoder input codeword 452 in a variable number of local iterations internal to the LDPC decoder 454.

Where the LDPC decoder 454 fails to converge (i.e., fails to yield the originally written data set) and the number of local iterations through LDPC decoder 454 exceeds a threshold, the resulting decoded output is provided as a decoded output 456 back to LEH memory 450 where it is stored awaiting another global iteration through data detector circuit 424 and LDPC decoder 454. Multiple sectors may be processed simultaneously in the data processing system 400, with additional sectors being admitted to the data detector 424 as other sectors converge in the LDPC decoder 454 and are output and cleared from the Y buffer 420 and LEH memory 450.

Stored decoded output 460 is retrieved from LEH memory 450 and is globally deinterleaved in global interleaver/deinterleaver circuit 444 to yield a globally deinterleaved output 462 that is stored to LE memory 434. The global deinterleaving reverses the global interleaving earlier applied to adjusted-seed output 442. Once data detector circuit 424 is available, a previously stored deinterleaved output 464 is accessed from LE memory 434 and locally deinterleaved by a deinterleaver circuit 466. Deinterleaver circuit 466 rearranges stored deinterleaved output 464 to reverse the shuffling originally performed by local interleaver circuit 430. A resulting deinterleaved output 470 is provided to data detector circuit 424 where it is used to guide subsequent detection of a corresponding codeword received as stored codeword 422. Thus, the term “global iteration” refers to the processing of data once through the data detector 424 and LDPC decoder 454 and the system elements between them during an iterative process in which the decoded output 456 is used to guide the data detector 424 during a subsequent global iteration. In contract, local decoding iterations take place during an iterative LDPC decoding operation within the LDPC decoder 454.

Alternatively, where the decoded output converges (i.e., yields the originally written data set) in the LDPC decoder 454, the resulting decoded output is provided as an output codeword 472 to a deinterleaver circuit 474. Deinterleaver circuit 474 rearranges the data to reverse both the global and local interleaving applied to the data to yield a deinterleaved output 476, stored in hard decision (HD) memory 480. The stored HD output 482 is provided to a controller 484. In some embodiments, controller 484 is a hard disk controller circuit which initiates read operations of a magnetic storage device and which receives the resulting data and provides it to an external device such as a general purpose computer system. A seed comparator 484 may be used to compare a specified LDPC seed 492 from the hard disk controller 484 with the decoded LDPC seed 490 from the HD memory 480 to ensure that the HD output 482 corresponds with the requested sector. With respect to FIG. 4, the term data processing system is used to refer to the entire illustrated read channel from analog input 402 to hard decision output 482 provided to controller 484.

Turning to FIG. 5, a flexible seed value circuit 500 is depicted in accordance with some embodiments of the present invention. The flexible seed value circuit 500 replaces the LLR values for the LDPC seed in the detector output 502 at various global iterations, yielding an updated LLR value for the LDPC seed at output 504. The flexible seed value circuit 500 bases the replacement on the global iteration number 506, a global iteration number threshold 510, high LLR values 512 and low LLR values 514. The global iteration number 506 may be provided by a global iteration scheduler 516, which in some embodiments is not part of the flexible seed value circuit 500, but part of a data processing system that includes the flexible seed value circuit 500. The global iteration number threshold 510 is retrieved from a user-programmable global iteration number threshold register 520. The high LLR values 512 are retrieved from a user-programmable LLR high value register 522. The low LLR values 524 are retrieved from a user-programmable LLR low value register 524. A comparator 526 compares the global iteration number 506 with a fixed iteration number 530, such as 1, yielding an output 532 that causes a multiplexer 534 to switch the high LLR values 512 to the output 536 when the data processing system is on the fixed iteration number 530. A comparator 540 compares the global iteration number 506 with the global iteration number threshold 510, yielding an output 542 that causes the multiplexer 534 to switch the low LLR values 514 to the output 536 when the data processing system is on the global iteration number threshold 510. An OR gate 546 asserts an output 550 that causes a multiplexer 552 to replace the LLR value for the LDPC seed in the detector output 502 with either the high LLR values 512 or low LLR values 514, depending on the global iteration number 506, when the global iteration number 506 is on the fixed iteration number 530 or on the global iteration number threshold 510. When the global iteration number 506 is not on the fixed iteration number 530 or on the global iteration number threshold 510, the multiplexer 552 outputs the detector output 502 with the unmodified LDPC seed LLR values as calculated in the upstream data detector at output 504.

Turning to FIG. 6, a flow diagram 600 depicts a method for processing data in a data processing system with flexible LDPC seed in accordance with various embodiments of the present inventions. Flow diagram 600 shows the method of processing data sectors that may be performed by circuit such as those disclosed in FIGS. 4 and 5. Following flow diagram 600, it is determined whether a data detector circuit is available. (Block 602) Where a data detector circuit is available (block 602), a data detection algorithm is applied to a data sector, guided by a data set derived from a decoded output where available from a central memory circuit (e.g., the second and later iterations through the data detector circuit and the data decoder circuit) to yield a detected output. (Block 604) In some embodiments of the present inventions, the data detection algorithm is a soft output Viterbi algorithm as is known in the art, yielding an output with LLR values representing the probability of possible data bit or symbol values. In other embodiments of the present inventions, the data detection algorithm is a maximum a posteriori data detector circuit as is known in the art. It is determined whether the data sector is on the first global iteration through the data detector and LDPC decoder. (Block 606) If so, the LLR values for the LDPC seed in the detected output are set to a user-programmable high LLR value. (Block 610) It is determined whether the global iteration number for the data sector is at a user-programmable global iteration number threshold. (Block 612) If so, the LLR values for the LDPC seed in the detected output are set to a user-programmable high low value. (Block 614) The detected output is interleaved, including interleaving the LDPC seed, to yield an interleaved detected output. (Block 616) In some embodiments, the detected output is also interleaved prior to changing the LLR values for the LDPC seed, although the LDPC seed itself is left in a contiguous block in the prior interleaving. The interleaved detected output is stored to a central memory circuit to await processing by a data decoder circuit. (Block 620) Notably, in the embodiment depicted in FIG. 4, the LE memory 434 and LEH memory 450 are part of such a central memory circuit.

In parallel to the previously discussed data detection processing, it is determined whether a data decoder circuit is available. (Block 630) Where the data decoder circuit is available (block 630) a previously stored derivative of a detected output is accessed from the central memory and used as a received codeword. (Block 632) The received codeword is iteratively processed in the data decoder circuit to yield a decoded output. (Block 634) In some embodiments of the present inventions, the data decoding algorithm is an LDPC decoding algorithm. Based upon the disclosure provided herein, one of ordinary skill in the art will recognize other decode algorithms that may be used in relation to different embodiments of the present inventions. A derivative of the decoded output is stored to the central memory circuit. (Block 636) A determination is made as to whether data values have converged in the data decoding circuit. (Block 640) In some embodiments, this includes determining whether log-likelihood ratio values representing the likelihood that decoded values for the data reach a particular threshold, and/or whether parity check equations for the data are satisfied. Where the data decoding converged (block 640), the decoded LDPC seed is compared with the expected LDPC seed to verify that the data sector is the expected sector. (Block 642) The decoded output may be transferred out as hard decision data and cleared from the central memory circuit, freeing space for another data sector to be read, detected and decoded. (Block 644) Alternatively, where the data decoding failed to converge (block 640), data processing continues with another local iteration (block 630) until the maximum number of local iterations has been performed, at which point another global iteration is performed (block 602).

Notably, the order in which the steps of FIG. 6 are performed is not limited to that shown, and steps may be performed in parallel. For example, multiple sectors may be processed together, being stored in the central memory circuit as space becomes available.

It should be noted that the various blocks discussed in the above application may be implemented in integrated circuits along with other functionality. Such integrated circuits may include all of the functions of a given block, system or circuit, or a portion of the functions of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent. In other cases, the one part of a given system, block or circuit may be implemented in software or firmware, while other parts are implemented in hardware.

In conclusion, the present invention provides novel apparatuses, systems, and methods for a data processing system with flexible LDPC seed. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. A data processing system comprising:
a data detector operable to generate detected values for data sectors, wherein each data sector includes a known value data segment, and wherein the detected values comprise log likelihood ratio values;
a data decoder operable to generate decoded values based on the detected values; and
a log likelihood ratio value setting circuit operable to change the log likelihood ratio values in the detected values for the known value data segments at particular global processing iterations before the data decoder.

2. The data processing system of claim 1, wherein the log likelihood ratio value setting circuit is operable to change the log likelihood ratio values in the detected values for the known value data segment to first values during a first global processing iteration number and to second values during a second global processing iteration number.

3. The data processing system of claim 2, wherein the first values are higher than the second values.

4. The data processing system of claim 3, wherein the first values represent a maximum probability value and wherein the second values represent a balanced probability value.

5. The data processing system of claim 4, wherein the first values are retrieved from a user-programmable high value register and the second values are retrieved from a user-programmable low value register.

6. The data processing system of claim 2, wherein the first global processing iteration number comprises the first global iteration.

7. The data processing system of claim 2, wherein the second global processing iteration number comprises a threshold value retrieved from a global iteration number threshold register.

8. The data processing system of claim 7, wherein the global iteration number threshold register is user programmable.

9. The data processing system of claim 1, further comprising an interleaver between an output of the log likelihood ratio value setting circuit and an input of the data decoder, operable to shuffle portions of the decoded values for one of the data sectors, including dividing the known value data segment.

10. The data processing system of claim 9, wherein the interleaver comprises a global interleaver, further comprising a local interleaver between an output of the data detector and an input of the log likelihood ratio value setting circuit, operable to shuffle portions of the decoded values for said one of the data sectors without dividing the known value data segment.

11. The data processing system of claim 1, wherein the known value data segment comprises a low density parity check seed value.

12. The data processing system of claim 1, wherein the known value data segment comprises a logical block address for a data sector.

13. The data processing system of claim 1, further comprising a comparator operable to compare the logical block address in the decoded values with an expected logical block address.

14. The data processing system of claim 1, wherein the data processing system is implemented as an integrated circuit.

15. The data processing system of claim 1, wherein the data processing system is incorporated in a storage device.

16. The data processing system of claim 1, wherein the data processing system is incorporated in a storage system comprising a redundant array of independent disks.

17. The data processing system of claim 1, wherein the data processing system is incorporated in a transmission system.

18. A method for processing data in a data processing system, comprising:
detecting values for a data sector to yield log likelihood ratio values for the data sector, wherein the data sector includes a known value data segment;
changing the log likelihood ratio values for the known value data segment to first values during a first global iteration in the data processing system;
changing the log likelihood ratio values for the known value data segment to second values during a later iteration in the data processing system, wherein the first values are higher than the second values; and
decoding the log likelihood ratio values for the data sector in a low density parity check decoder.

19. The method of claim 18, further comprising interleaving the log likelihood ratio values for the data sector, including dividing the known value data segment, before the decoding and after the changing.

20. A storage system comprising:
a storage medium maintaining a data set;
a read/write head assembly operable to sense the data set on the storage medium and to provide an analog output corresponding to the data set;
an analog to digital converter operable to sample a continuous signal to yield a digital output; and
a data processing system comprising:
a data detector operable to generate detected values for data sectors in the digital output, wherein each data sector includes a known value data segment, and wherein the detected values comprise log likelihood ratio values;
a data decoder operable to generate decoded values based on the detected values; and
a log likelihood ratio value setting circuit operable to change the log likelihood ratio values in the detected values for the known value data segments at particular global processing iterations before the data decoder.
